(19) United States
(12) Patent Application Publication
(10) Pub. No.: US 2020/0083360 A1
(43) Pub. Date: Mar. 12, 2020

(54) III-N TRANSISTORS WITH POLARIZATION MODULATION

(71) Applicant: Intel Corporation, Santa Clara, CA (US)

(72) Inventors: Walid Hafez, Portland, OR (US); Han Wui Then, Portland, OR (US); Sansaptak Dasgupta, Hillsboro, OR (US); Marko Radosavljevic, Portland, OR (US); Paul Fischer, Portland, OR (US)

(73) Assignee: Intel Corporation, Santa Clara, CA (US)

(21) Appl. No.: 16/126,884

(22) Filed: Sep. 10, 2018

(51) Int. Cl. H01L 29/778; H01L 29/20; H01L 29/66; H01L 29/423; H01L 23/31; H01L 21/308; H01L 27/088

(52) U.S. Cl. CPC H01L 29/778; H01L 29/2003; H01L 29/66462; H01L 27/088; H01L 23/3171; H01L 21/3086; H01L 29/42356

(57) ABSTRACT

III-N transistor structure with modulation in the thickness of a III-N material that induces a 2D carrier gas within another III-N material. A thickness of the III-N material within a first distance between a gate terminal and second transistor terminal may be lower than a thickness of the III-N material within a second distance between the gate terminal and a third transistor terminal. Carrier density within the 2D carrier gas, as driven by the thickness modulation, may be lower within a distance between a gate electrode and a second terminal of the transistor. With lower carrier density, more voltage may be dropped over a given distance. Lateral dimensions of a transistor capable of sustaining a given gate-drain voltage, for example, may be reduced.

### BACKGROUND

Demand for integrated circuits (ICs) in portable electronic applications has motivated greater levels of semiconductor device integration. Many advanced semiconductor devices in development leverage non-silicon semiconductor materials, some of which offer the potential of high breakdown voltages. The group III-nitride (III-N) material system shows particular promise for high voltage and high frequency applications like power management ICs and RF power amplifiers.

GaN transistors fabricated for a high breakdown voltage have conventionally had lateral device architectures with dimensions significantly larger than a minimum-size transistor. For example, a conventional lateral GaN power transistor 101 is illustrated in FIG. 1. Transistor 101 includes a first III-N material 105. A second III-N layer 110 is over III-N layer 105 to form a two-degree carrier gas (2DEG) 112. A portion of carrier gas 112 spans a lateral gate-to-drain spacing L₁ between a gate stack 115 and drain 125. Carrier gas 112 also spans a second distance between gate stack 115 and a source 120. For metal-semiconductor field effect transistor (MESFET) architectures, gate stack 115 includes only a gate electrode forming a Schottky junction with III-N material 110. For metal-insulator-semiconductor field effect transistor (MISFET) architectures, gate stack 115 comprises a gate electrode and a gate dielectric separating the gate electrode from III-N material 110.

For high breakdown voltage applications (e.g., V_{D}-V_{G} of 50V-100V, or more), lateral gate-drain spacing L₁ may be significantly longer than lateral gate-source spacing L₂. For example, lateral gate-drain spacing L₁ may be well over 5 μm while lateral gate-source spacing L₂ may be submicron. Such a large gate-drain spacing is often required to ensure there is sufficient voltage drop over gate-drain spacing L₁ to avoid premature gate breakdown in the presence of electric fields that increase in strength with decreasing lateral gate-drain spacing L₁. Lateral gate-drain spacing L₁ may need to be particularly large for MISFET architectures as the MIS gate junction may have a lower breakdown voltage than a Schottky junction. With the lateral gate-drain pitch L₁ then unable to shrink for a given breakdown voltage specification, opportunities for scaling the source-drain pitch are limited in such devices.

III-N power transistor architectures that enable smaller source-drain pitch for a given minimum breakdown voltage, and are scalable would be advantageous for both discrete III-N power devices and SoC applications (e.g., power management IC s and RF power amplifiers) where III-N power transistors are integrated with other devices, such as transistors not designed for such a high breakdown voltage (e.g., low voltage FETs).

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a conventional lateral III-N power transistor;

FIG. 2A is a cross-sectional profile view of III-N transistor structure with polarization modulation, in accordance with some embodiments;

FIG. 2B is a plan view of the III-N transistor structure shown in FIG. 2A, in accordance with some embodiments;

FIG. 3A is a cross-sectional profile view of III-N transistor structure with polarization modulation, in accordance with some embodiments;

FIG. 3B is a plan view of the III-N transistor structure shown in FIG. 2A, in accordance with some embodiments;

FIG. 4 and FIG. 5 are cross-sectional profile views of III-N transistor structures with polarization modulation, in accordance with some embodiments;

FIG. 6 is a cross-sectional profile view of an integrated circuit including both a III-N transistor structure with polarization modulation, and a III-N transistor structure without polarization modulation, in accordance with some embodiments;

FIG. 7 is a flow diagram illustrating methods of forming a III-N transistor structure with polarization modulation, in accordance with some embodiments;

FIGS. 8A, 8B, 8C, 8D, and 8E are cross-sectional views of III-N transistor structures as selected operations in the method illustrated in FIG. 7 are performed, in accordance with some embodiments;

FIG. 9 illustrates a mobile computing platform and a data server machine employing an SoC including III-N transistors with polarization modulation, in accordance with embodiments; and

FIG. 10 is a functional block diagram of an electronic computing device, in accordance with some embodiments.

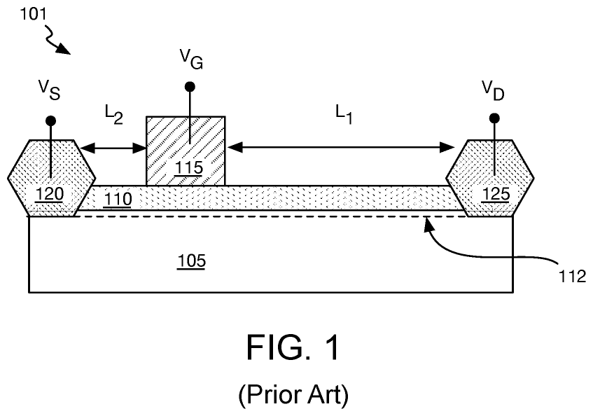

### DETAILED DESCRIPTION

Described herein are III-N transistor structures, and methods of fabricating such devices. In the following description, numerous specific details are set forth, such as exemplary device architectures, to provide a thorough understanding of embodiments of the present disclosure. However, it will be apparent to one skilled in the art, that the present disclosure may be practiced without these specific details. In some instances, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

Certain terminology may also be used in the following description for the purpose of reference only, and thus are not intended to be limiting. For example, terms such as “top,” “bottom,” “upper”, “lower”, “over,” “above”, “under,” and “below” refer to directions in the drawings to which reference is made. Terms such as “front”, “back”, “rear”, and “side” describe the orientation and/or location of portions of the component within a consistent but arbitrary frame of reference, which is made clear by reference to the text and the associated drawings describing the component under discussion. Such terminology may include the words specifically mentioned above, derivatives thereof, and words of similar import. The terms “over,” “under,” “between,” and “on” may also be used herein to refer to a relative position of one component or material with respect to other components or materials where such physical relationships are noteworthy. For example, in the context of materials, one material or material disposed over or under another may be directly in contact or may have one or more intervening materials. Moreover, one material disposed between two materials may be directly in contact with the two layers or may have one or more intervening layers. In contrast, a first material “on” a second material is in direct contact with that second material/material. Similar distinctions are to be made in the context of component assemblies.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

In embodiments described further herein, a thickness of a III-N material that induces a 2D carrier gas within another III-N material (i.e., a polarization layer) is varied to modulate a carrier density of states within a gate-to-drain and/or gate-to-source spacing of a transistor structure. In some exemplary embodiments, a thickness of the III-N polarization material within a gate-to-drain spacing may be less than a thickness of the III-N polarization material within other regions of the transistor (e.g., below the gate electrode, and/or within the gate-to-source spacing). As one result of such thickness modulation, for example, a carrier density within a least some portion of the gate-to-drain spacing may be lower than within at least a portion of the gate-to-source spacing. The transistor structure may then achieve both a low source “on-state” resistance, and sustain a larger voltage drop over a given gate-to-drain spacing to permit greater gate-to-drain voltages during transistor operation. In some such embodiments where the transistor is a MISFET, gate dielectric breakdown may be avoided even at high gate-to-drain voltages since the electric field across the gate dielectric will be a weaker function of the gate-to-drain voltage. Lateral dimensions of a transistor capable of sustaining a given gate-to-drain voltage may also be reduced. For example, where low voltage and high voltage transistors are present within a single IC, the footprint of the two transistors may be more nearly the same when polarization material thickness within the gate-to-drain spacing of the high voltage transistor is thinner than the polarization material thickness within the gate-to-drain spacing of the low voltage transistor.

In some other exemplary embodiments, a thickness of the III-N polarization material within a gate-to-source spacing may be less than a thickness of the III-N polarization material within other regions of the transistor (e.g., below the gate electrode, and/or within the gate-to-drain spacing). As one result of such thickness modulation, for example, a carrier density within at least some portion of the gate-to-source spacing is lower than within at least a portion of the gate-to-drain spacing. The transistor structure may then implement a source side ballasting resistance, while maintaining a low extrinsic drain resistance.

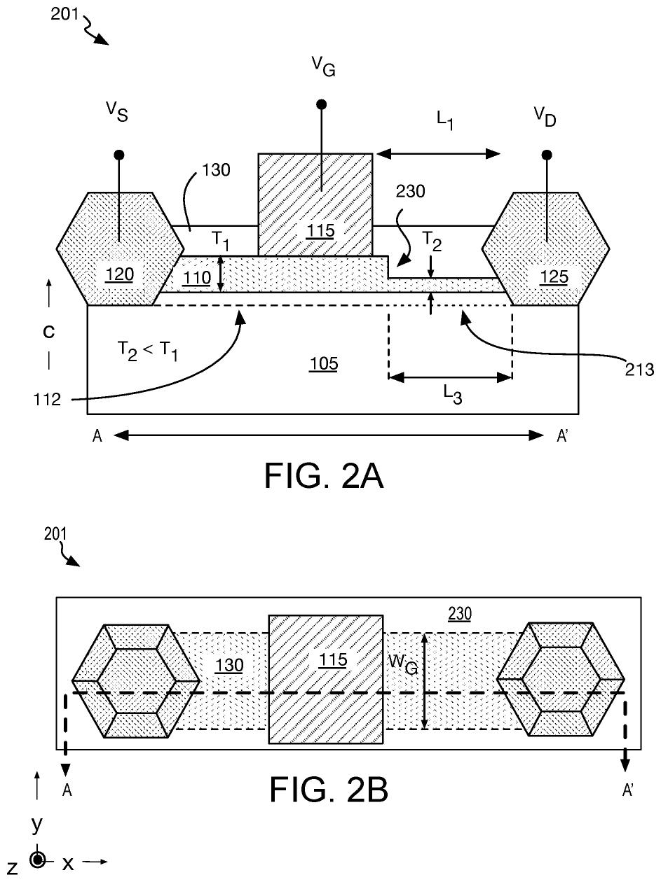

FIG. 2A is a cross-sectional profile view of III-N transistor structure 201 with polarization modulation, in accordance with some embodiments. FIG. 2B is a plan view of the III-N transistor structure 201, in accordance with some embodiments. The dashed A-A′ line illustrated in FIG. 2B demarks where the plane of the profile shown in FIG. 2A.

III-N transistor structure 201 may be over any suitable substrate (not depicted). In some embodiments, the substrate is crystalline SiC. In other embodiments, the substrate is a cubic semiconductor, such as monocrystalline silicon. For such embodiments, III-N transistor structure 201 may be formed over a cubic substrate surface, such as a (100) surface. III-N crystals may also be grown on other surfaces (e.g., 110, 111, miscut or offcut, for example 2-10° toward [110] etc.). III-N transistor structure 201 may also be over a host substrate material upon which the III-N crystal has been bonded, in which case the host substrate may be crystalline, or not (e.g., glass, polymer, etc.).

III-N transistor structure 201 includes a first III-N material 105 and a second III-N material 110. III-N material 105 and 110 may each have substantially monocrystalline microstructure (e.g., hexagonal Wurtzite). Although monocrystalline, it is noted that crystal quality of III-N crystalline materials may vary dramatically, for example as a function of the techniques employed to form materials 105 and 110. In some exemplary embodiments, dislocation density with III-N material layer 105 is in the range of 10⁶-10¹¹/cm². FIG. 2A illustrates crystal orientations of III-N materials 105 and 110, in accordance with some embodiments where the thickness of the materials along a c-axis of the crystal is approximately on the z-axis, substantially orthogonal to a plane of an underlying substrate. In this orientation, the crystal structure of III-N materials 105 and 110 lack inversion symmetry with the (0001) and (000−1) planes not being equivalent. In illustrated embodiments, III-N materials 105 and 110 may be characterized as having +c polarity with the c-axis extending in the <0001> direction.

III-N material 105 comprises nitrogen as a first majority lattice constituent and a second majority lattice constituent including one or more elements from Group III of the Periodic table. III-N material 105 may be any III-N material known to be suitable as a transistor channel material. In some embodiments, III-N material 105 is a binary alloy (e.g., GaN, AlN, InN). In some such embodiments that have an advantageous high carrier mobility, III-N material 105 is binary GaN. In some other embodiments, III-N material 105 is a ternary alloy (e.g., In_{y}Al_{1-y}N, InₓGa₁₋ₓN, or AlₓGa₁₋ₓN). In still other embodiments, III-N material 105 is a quaternary alloy (e.g., In_{y}Al_{1-y-z}Ga_{z}N). III-N material 105 may have any impurity dopants. However, in some advantageous embodiments, III-N material 105 is intrinsic and not intentionally doped with impurities associated with a particular conductivity type. For example, intrinsic impurity (e.g., Si) level in III-N material 105 may be advantageously less than 1e17 atoms/cm³, and in some advantageous embodiments is between 1e14 and 1e16 atoms/cm³.

III-N material 110 also comprises nitrogen as a first majority lattice constituent and a second majority lattice constituent including one or more elements from Group III of the Periodic table. III-N material 110 may be any III-N material known to be suitable as a polarization material for the chosen III-N material 105. III-N material 110 may comprise any alloy distinct from that of III-N material 105 so as to provide a variation in the polarization field strength (e.g., spontaneous and/or piezoelectric) between these two III-N materials. Where spontaneous and/or piezoelectric polarization field strengths are sufficiently different between III-N material 105 and III-N material 110, a two-dimensional charge carrier sheet (e.g., 2D electron gas or “2DEG”) is formed within III-N material 105 in the absence of any externally applied field. The 2DEG can be expected to be present in III-N material 105 and located within a few nanometers of the heterojunction with III-N material 110. III-N material 110 may therefore be referred to in functional terms as a “polarization layer” as it induces a polarization charge into the heterostructure, and III-N transistor structure 201 may therefore be referred to as a heterojunction field effect transistor (HFET). In some embodiments, III-N material 110 comprises a binary alloy (e.g., GaN, AlN, InN). In some other embodiments, III-N material 110 comprises a ternary alloy (e.g., In_{y}Al_{1-y}N, InₓGa₁₋ₓN, or AlₓGa₁₋ₓN). In still other embodiments, III-N material 110 comprises a quaternary alloy (e.g., In_{y}Al_{1-y-z}Ga_{z}N). In some such embodiments, x is between 0.25 and 0.4, y is less than 0.2, or z is less than 0.2. In some embodiments, III-N material 110 has a greater amount of Al than does III-N material 105. In some such embodiments, III-N material 110 includes a layer of binary AlN. In further embodiments, III-N material 110 may comprise multiple layers, each having a distinct alloy composition.

Transistor structure 201 further includes a source 120 and a drain 125 with a gate stack 115 between source 120 and drain 125. During operation, source 120 may be biased as a first circuit node at a source voltage V while drain 120 may be biased as a second circuit node at a drain voltage V_{d}. Gate stack 115 includes at least a gate electrode that may be biased during transistor operation as a third circuit node at a gate voltage V_{g} suitable for controlling conduction through a channel portion of transistor structure 201. The source and drain 120, 125 may each extend through III-N material 110, landed on, or embedded within, III-N material 105. In the illustrated example, source and drain 120, 125 are each in physical contact with a c-plane (e.g., Ga-face) of III-N. Source and drain 120, 125 each have access to an edge thickness of 2D charge carrier sheet within some nanometers of the heterojunction between and III-N materials 105 and 110. Modulation of the 2D charge carrier sheet by the field effect of may thereby control electrical coupling between source 120 and drain 125. The junction between III-N material 105 and source and drain 120, 125 may be a homojunction or a heterojunction with the composition of source and drain 120, 125 being distinct from that of III-N material 105. In some embodiments, source and drain 120, 125 are both also III-N material(s). For example, source and drain 120, 125 may both be InGaN. Some advantageous InGaN embodiments include 5-20% In (InₓGa₁₋ₓN with 5%≤x≤20%). The alloy composition of source and drain 120, 125 may be constant or graded between III-N material 105 and a contact metal (not depicted). For some embodiments, source and drain 120, 125 are epitaxial, having the same crystallinity and orientation as III-N material 105. Exemplary hexagonal crystal facets are illustrated in FIGS. 2A and 2B. For some other embodiments, source and drain 120, 125 are polycrystalline, in which case crystal facets may not be as readily apparent.

Source and drain 120, 125 may each be semiconductor material, which may be impurity doped to a desired conductivity type (e.g., with Si for n-type). The doping level of both the source and drain 120, 125 is advantageously as high as practical for lowest transistor terminal/access resistance. The doping level of source and drain 120, 125 may be at least an order of magnitude higher than that of III-N material 105, for example. In some exemplary embodiments where the source 120 and/or drain 125 is a III-N alloy, the impurity dopant level is over 1e19 atoms/cm³, and more advantageously over 1e20 atoms/cm³. Si is one exemplary dopant atom for which such high (N+) doping levels may be achieved in III-N alloys. An alternative N-type dopant is Ge.

In some MISFET embodiments, gate stack 115 comprises both a gate electrode and a gate dielectric that is between the gate electrode and an underlying III-N material (either III-N material 110 or III-N material 105). For either MISFET or MESFET embodiments, the composition of a gate electrode may be any known to be suitable for the purpose. In some embodiments, where III-N material 105 is binary GaN, an exemplary gate electrode may include at least one of Ni, W, Pt, or TiN. Each of these metals or metallic compounds may be associated with a particular work function (or metal-semiconductor work function difference) that may have some impact on transistor threshold voltage. A gate electrode may also be any metal/metallic compound known to make a rectifying contact to III-N material 105 and/or 110.

Transistor structure 201 further includes a passivation material 130 covering III-N material 110. Passivation material 130 may also cover at least a portion of a sidewall of source 120 and/or drain 120, as illustrated. Passivation material 130 may further at least partially backfill any recesses with III-N material 110. Passivation material 130 may have any composition known in the art to reduce dangling bonds and/or other surface defect states in III-N material 110 that may result in high transistor leakage currents. In some examples, passivation material 130 includes silicon and oxygen (e.g., silicon oxides or silicon oxynitrides). In some examples, passivation material 130 includes silicon and nitrogen (e.g., silicon oxynitrides or silicon nitride). In other embodiments, passivation material 130 includes a metal and oxygen (e.g., aluminum oxide, hafnium oxide, or titanium oxide). In still other examples, passivation material 130 comprises another III-N material, for example having a wider bandgap than that of III-N material 110. Passivation material 130 may therefore have any microstructure (e.g., amorphous, polycrystalline or monocrystalline).

In addition to a dependency on the polarization strength of III-N material 110 (e.g., relative to that of III-N material 105), the charge carrier (e.g., electron) density of the 2DEG present within III-N material 105 may vary as a function of a thickness (along the polar, or c-axis) of III-N material 110. Thickness variation may modulate the realization of both spontaneous and piezoelectric polarizations, with greater thickness of III-N material 110 increasing the differential in polarization strengths between III-N material 105 and III-N material 110 until some saturation level. Carrier sheet density within III-N material 105 can be accordingly be modulated within transistor structure 201, for example beyond either, or both, edges of gate stack 115.

In some embodiments herein, the thickness of III-N material 110 varies over a lateral distance (e.g., x-dimension in FIGS. 2A and 2B) between source 120 and drain 125. For the illustrated embodiments, the thickness of III-N material 110 more specifically varies over a lateral gate-to-drain spacing L₁ between at edge or sidewall of gate stack 115 and drain 125. In the example illustrated in FIG. 2A, a region of III-N material 110 between source 120 and gate stack 115 has a first c-axis thickness T₁, which is larger than a second c-axis thickness T₂ of III-N material 110 in a region within the gate-to-drain spacing L₁. As further illustrated in FIG. 2A, there is a 2DEG 112 having a first (e.g., higher) electron density of states within regions of III-N material 105 that are below III-N material 110 that have thickness T₁. A 2DEG 213 having a second (e.g., lower) electron density of states is within regions of III-N material 105 that are below III-N material 110 that has thickness T₂. In the embodiments illustrated in FIG. 2A, III-N material 110 located between gate stack 115 and III-N material 105 has substantially the same thickness T₁ as the source-to-drain spacing. Hence, modulation of III-N material 110 occurs only within gate-to-drain spacing L₁. In the illustrated example, III-N material 110 has a step function thickness modulation 230. However, more gradual thickness modulation functions are also possible, such as, but not limited to, a monotonically decreasing thickness from T₁ to T₂. Although not illustrated, a similar polarization layer thickness modulation may be implemented on the source side of transistor structure 201, either instead of, or in addition to, the illustrated drain-side thickness reduction.

Modulation of the thickness of III-N material 110 may be tuned to achieve desired transistor parametrics. For example, magnitude of the modulation (e.g., the difference between T₁ to T₂), location of the modulation (e.g., within gate-to-drain spacing L₁, within a gate-to-source spacing), and lateral length of the modulation (e.g., the % of gate-to-drain spacing L₁ occupied by III-N material 110 having thickness T₂) may all be predetermined to achieve a desired transistor performance (e.g., desired minimum breakdown voltage). In some embodiments, thickness T₂ is less than 90% of thickness T₁. In some further embodiments, thickness T₂ is no more than 80% of thickness T₁. In the example shown in FIG. 2A, thickness T₂ is less than 50% of thickness T₁, and may be as little as 10-20% of thickness T₁, or even less. In one specific example, where III-N material 105 is binary GaN, and III-N material 110 comprises at least an AlGaN material layer, thickness T₁ is at least 3 nm (e.g., 3-10 nm) with thickness T₂ being less than 3 nm (e.g., 0.1-2.5 nm). The magnitude of thickness modulation may range from approximately 0.5 nm to 3 nm, or more. In some further embodiments, the location of the modulation is more proximal to the gate than to the drain (or more proximal to the gate than to the source). For example, as illustrated in FIG. 2A, step function thickness modulation 230 is near a sidewall of gate stack 115. In other embodiments step function thickness modulation 230 may be self-aligned to a sidewall of gate stack 115. In some alternative embodiments, the location of the thickness modulation is more proximal to drain 125 than to gate stack 115 (or more proximal to the source than to the gate stack). For example, step function thickness modulation 230 may be self-aligned to a sidewall of drain 125 (not depicted). In the illustrated example, since there is only a single step function thickness modulation 230, the lateral length of the modulation is dependent on the location of the modulation. Specifically, within gate-to-drain spacing L₁, III-N material 110 has thickness T₂ over the lateral length L₃.

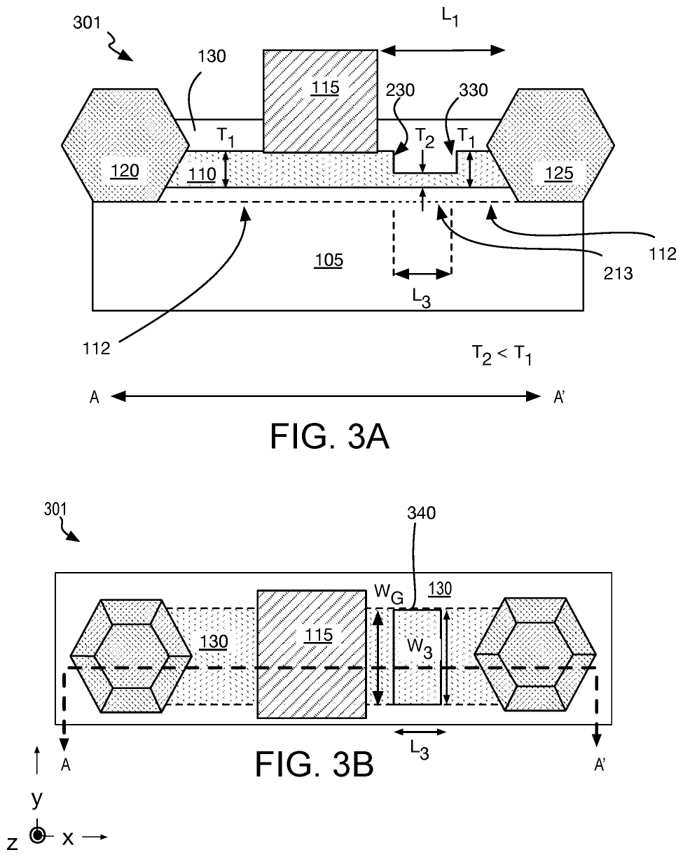

In some embodiments, a polarization material within a transistor structure may be modulated multiple times. FIG. 3A is a cross-sectional profile view of III-N transistor structure 301 with polarization modulation, in accordance with some embodiments. FIG. 3B is a plan view of the III-N transistor structure 301, in accordance with some embodiments. As shown in FIG. 3A, there is both a step function thickness modulation 230 where III-N material 110 transitions from thickness T₁ to thickness T₂, and a return step function thickness modulation 330 where III-N material 110 transitions from thickness T₂ back to thickness T₁. As such, 2DEG 112 is present within the source-to-gate spacing, under gate stack 115, and also proximal to drain 125, with 2DEG 213 intervening therebetween. A structure where III-N material 110 returns to thickness T₂ at the drain interface may be advantageous for lower resistance immediately at the junction of drain 125, if desired. A similar structure (e.g., mirror image of FIG. 3A) may be implemented on the source-side, for example to fabricate a ballasting resistor that retains low resistance immediately at the junction of source 120.

As further shown in FIG. 3A, 2DEG 213 is below a trench, or recess, of lateral length L₃ in III-N material 110 located within gate-to-drain spacing L₁. Lateral length L₃ may have any dimension (e.g., from tens of nanometers to microns) smaller than gate-to-drain spacing L₁. The plan view of FIG. 3B further illustrates the polygonal shape (e.g., rectangular strip) of a thin polarization region 340. In the illustrated embodiments, thin polarization region 340 has a width W₃ that is substantially equal to a width W_{G} of gate stack 115 (i.e., equal to the transistor channel width). All gate-to-drain current will therefore pass through thin polarization region 340. Width W₃ may however be less than width W_{G}.

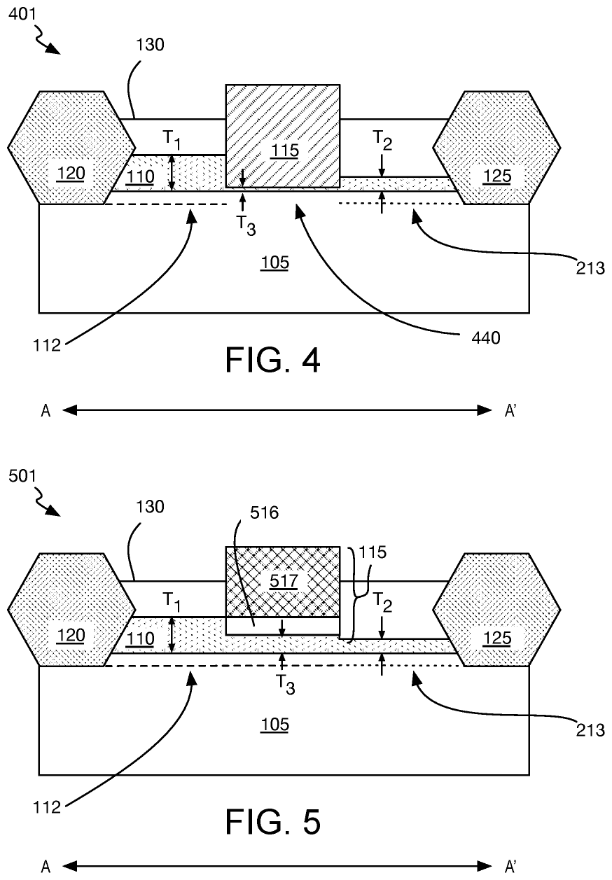

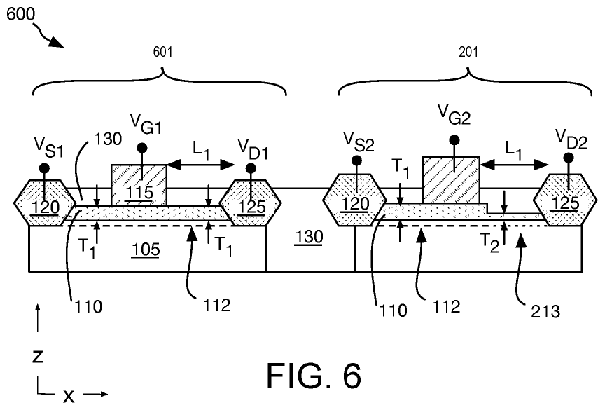

FIG. 4 and FIG. 5 are cross-sectional profile views of III-N transistor structures with polarization modulation, in accordance with some further embodiments. In FIG. 4, transistor structure 401 comprises a recessed gate electrode. Gate stack 115 is located within a recess in the underlying III-N material that extends a depth (e.g., z-dimension) through at least a portion of III-N material 110. While gate stack 115 may be recessed potentially completely through III-N material 110, in some advantageous embodiments, III-N material 110 has a non-zero c-axis thickness T₃ below gate stack 115. The recess depth into III-N material 110 may be predetermined, for example to tune threshold voltage (V₁) of the transistor. Thickness T₃ may therefore be different than both thickness T₁ and thickness T₂. In some embodiments, the III-N polarization material thickness within a gate-to-drain spacing is less than the III-N polarization material thickness within a source-to-gate spacing, but greater than the III-N polarization material thickness immediately below a gate stack. For example, thickness T₃ may be targeted to be less than a few nanometers (e.g., 0.1-1.5 nm) to ensure a positive Vₜ for an enhancement mode n-type transistor with no 2DEG within the channel region 440 at 0V source-gate bias (in contrast to transistor structure 201 that may have a negative Vₜ suitable for a depletion mode n-type transistor). For transistor structure 401, thickness T₁ may be independently targeted, for example to ensure a low source-gate resistance, as noted above. Thickness T₂ may be independently targeted, for example to be somewhat less than thickness T₁ to ensure a sufficient gate-drain resistance, as noted above. In some alternative embodiments, the III-N polarization material thickness within a source-to-gate spacing is less than the III-N polarization material thickness within a gate-to-drain spacing, but greater than the III-N polarization material thickness immediately below a gate stack.

FIG. 5 illustrates a transistor structure 501 in which gate stack 115 includes a gate dielectric 516 between a gate electrode 517 and III-N material 110. Transistor structure 501 specifically illustrates one example where polarization modulation is incorporated into an exemplary MISFET architecture. As shown, III-N material 110 below gate dielectric 516 has a thickness T₃ that is less than the thickness T₁ of III-N material 110 between source 120 and gate dielectric 516. Alternatively, thickness T₃ may be the same (or even greater than) thickness T₁ with thickness T₂ being less than thickness T₁. Thickness T₂ may again be greater than, equal to, or less than, thickness T₃.

Gate dielectric 516 may comprise any materials known to be suitable for the purpose, such as, but not limited to, silicon dioxide, silicon nitride, silicon oxynitride, and materials having a higher relative permittivity than silicon nitride (i.e., “high-k” dielectrics). Some examples of high-k dielectrics include aluminum oxides, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, tantalum oxide, tantalum silicon oxide, lead scandium tantalum oxide, and lead zinc niobate. Gate dielectric 516 may also have any suitable thickness with some examples being in the range of 3-50 nm.

In some further embodiments, an IC that includes a transistor (e.g., MISFET or MESFET) structure having a modulated polarization layer thickness further includes a transistor (e.g., MISFET or MESFET) structure that lacks such modulation. Some transistors of an IC may, for example, be designed for lower operating voltages and therefore may have a constant polarization material thickness optimized for lowest external resistance while other transistors of the IC designed for higher operating voltages may have a polarization material thickness that is modulated to some lower thickness on the drain side. Some transistors of an IC may, for example, be designed with a ballasting resistor at the source node and may have a polarization material thickness that is modulated to some lower thickness on the source side.

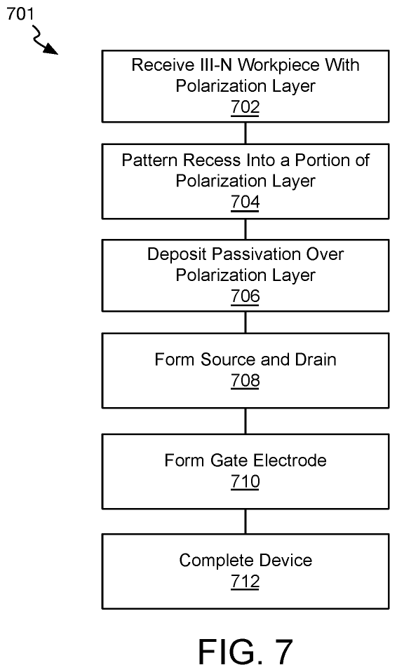

FIG. 6 is a cross-sectional profile view of an integrated circuit 600 including III-N transistor structure 201 and a III-N transistor structure 601. In some advantageous embodiments, both III-N transistor structure 201 and III-N transistor structure 601 are MISFETs employing substantially the same gate dielectric. While III-N transistor structure 201 comprises a III-N material 110 with thickness modulation in accordance with one or more of the embodiment described above, III-N transistor structure 601 comprises a III-N material 110 without such thickness modulation. For example, in III-N transistor structure 601 III-N material 110 has c-axis thickness T₁ between source 120 and gate stack 115, and also has c-axis thickness T₁ between gate stack 115 and drain 125. As shown in FIG. 6, in view of the difference in polarization layer thickness, III-N transistor structure 201 has a gate-to-drain length L₁ that is less than 5 μm, and may be sub-micron. In the illustrated embodiment, transistor structure 201 has a gate-to-drain length L₁ that is substantially equal (e.g., no more than 10% longer than that of III-N transistor structure 601 (e.g., both sub-micron). Nevertheless, III-N transistor structure 201 may sustain a V_{G2}-V_{D2} voltage higher than V_{G1}-V_{D1}. Hence, at least with respect to the illustrated dimension, III-N transistor structures having higher voltage ratings need not be significantly larger than III-N transistor structures of lower voltage ratings (and may, in some instances, have substantially the same footprint unless larger channel widths are desired for one or the other).

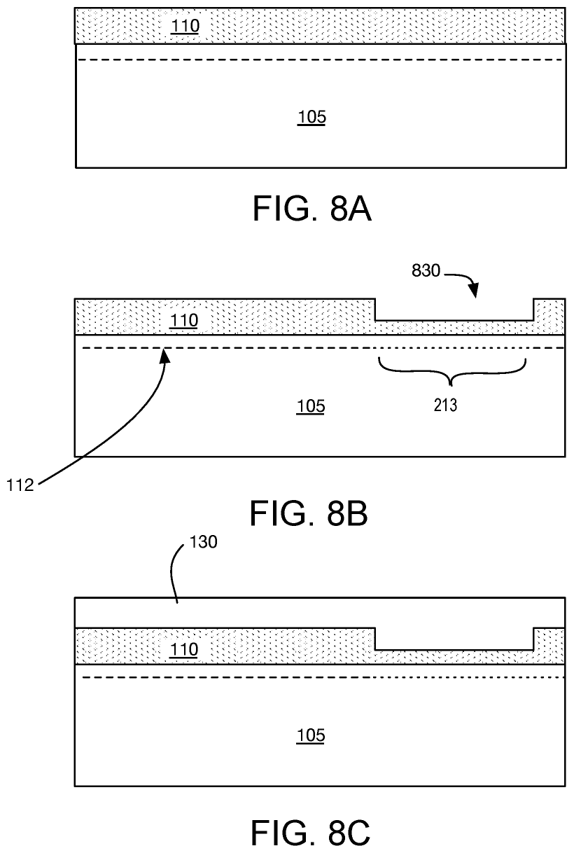

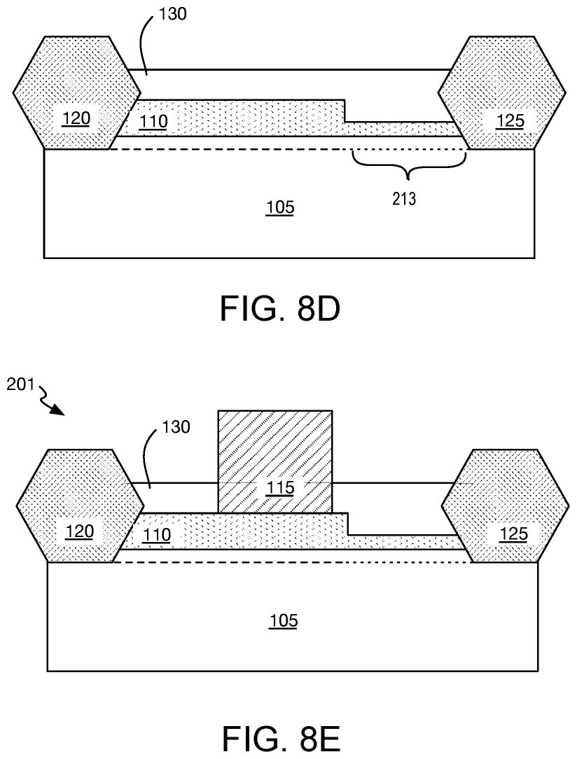

The transistor architectures described above may be fabricated according to a variety of techniques. FIG. 7 is a flow diagram illustrating methods 701 for forming a III-N transistor, in accordance with some embodiments. Methods 701 begin with receiving a workpiece at operation 702. Various epitaxial growth processes and/or fabrication processes may be employed upstream of methods 701 to prepare the workpiece received at operation 702. For some advantageous embodiments, the workpiece received at operation 702 comprises a substrate of crystalline group-IV materials (e.g., Si, Ge, SiGe). In some embodiments, the substrate received is a substantially monocrystalline (111) silicon substrate. Lattice mismatch between silicon and III-N crystals is most easily accommodated for the (111) plane. Nevertheless, other crystallographic orientations having greater lattice mismatch are also possible, such as, but not limited to, the (100), or (110) plane. A substrate may be bulk semiconductor or may be semiconductor on insulator (SOI). Substrate materials other than silicon are also possible, with examples including silicon carbide (SiC), sapphire, a III-V compound semiconductor (e.g., GaAs, InP). Substrates may have any level of impurity doping. Depending on the substrate, the workpiece received at operation 702 may include any number and/or thicknesses of III-N material layers. For example, the workpiece may include any III-N buffer architecture known to be suitable for the substrate, and may further include a III-N material layer known to be suitable as a transistor channel material, such as any of those described above. Over the channel material, the workpiece further includes any III-N material layer known to be suitable as a polarization material, such as any of those described above. FIG. 8A illustrates one exemplary workpiece that includes III-N material 110 over III-N material 105.

Returning to FIG. 7, methods 701 continue at operation 704 where a recess is patterned into a portion of the polarization material layer. Patterning of the recess may entail any masking and etching process known to be suitable for the polarization material chosen, for example. Masking may comprise hardmasks and/or photodefinable mask materials. Etching may comprise wet chemical or dry (plasma) etch processes, for example. As further shown in FIG. 8B, recess 830 has been formed through a partial thickness of III-N material 110 (e.g., by etching through at least 20% of the as-deposited thickness of the polarization layer, thereby modulating the 2D charge sheet between 2DEG 112 and 2DEG 213.

Returning to FIG. 7, methods 701 continue at operation 706 where a passivation layer is deposited over the polarization material layer. Any deposition process known to be suitable for the chosen passivation material may be implemented at operation 706. For example, a dielectric comprising both silicon and oxygen may be deposited by physical vapor deposition (PVD) or chemical vapor deposition (CVD). As another example, a wide band gap III-N material may be deposited by epitaxy over the polarization material layer. In the example further illustrated in FIG. 8C, passivation material 130 has been deposited over both recessed and unrecessed regions of III-N material 110, for example at least partially backfilling the recess formed at operation 704.

Returning to FIG. 7, methods 701 continue at operation 708 where the transistor source and drain are formed according to any techniques known to be suitable. In the example shown in FIG. 8D, a patterning process is employed to form openings through passivation material 130 and expose portions of III-N material 110. Within these openings, III-N material 110 may be removed, for example with an etch process similar to that employed at operation 704, albeit for a longer process time to ensure the underlying III-N material 105 is exposed. III-N material 105 may be similarly etched, for example with any wet chemical or dry etch process known to be suitable, to reveal a sidewall that intersects 2DEG 213 (or intersects 2DEG 112 depending on the relative position of source 120 and/or drain 125 to the recess that was formed at operation 704). Source and drain material, such as any of those III-N semiconductors described above, may then be deposited or epitaxial grown within the source and drain openings to arrive at the structure illustrated in FIG. 8D.

Returning to FIG. 7, methods 701 continue at operation 710 where a gate electrode is formed. In some embodiments, operation 710 further entails the formation of a gate dielectric. In some embodiments, operation 710 further entails a recessing of at least a portion of III-N material 110. Recessing of the gate may for example comprise a same etch process employed at operation 704 and/or operation 708. Any techniques known to be suitable for forming a gate stack including at least a gate electrode may be employed as embodiments herein are not limited in this context. In the example illustrated in FIG. 8D, a mask may be employed to pattern another opening in passivation material 130. Within this opening another portion of III-N material 110 may be exposed. A partial thickness of III-N material 110 may be removed, for example with an etch process similar to that employed at operation 704 (FIG. 7). Methods 701 then complete at operation 712 where any backend processes may be performed, for example to interconnect multiple transistor structures into an IC according to any known techniques.

Notably, methods 701 may be practiced at a wafer level with operation 704 performed only selectively over the wafer such that transistors with and without polarization layer thickness modulation can be fabricated concurrently. Also of note, no particular order is required to be maintained by methods 701. For example, the operations illustrated in FIG. 7 are numbered consecutively for the sake of discussion and the associated operations need not be so ordered.

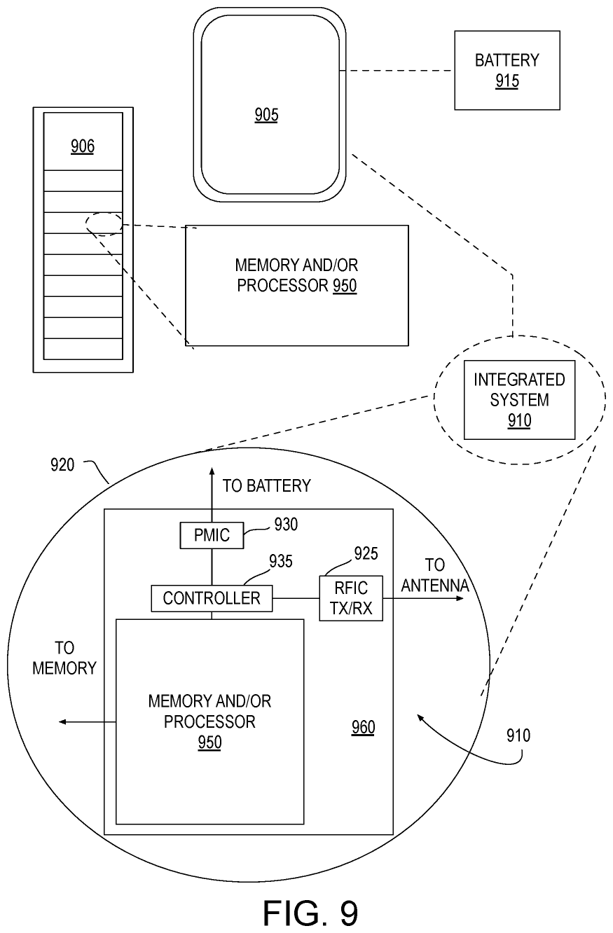

FIG. 9 illustrates a system in which a mobile computing platform 905 and/or a data server machine 906 employs an IC including at least one III-N power transistor having a laterally modulated polarization layer thickness, for example as described elsewhere herein. The server machine 906 may be any commercial server, for example including any number of high-performance computing platforms disposed within a rack and networked together for electronic data processing, which in the exemplary embodiment includes a packaged IC 950. The mobile computing platform 905 may be any portable device configured for each of electronic data display, electronic data processing, wireless electronic data transmission, or the like. For example, the mobile computing platform 905 may be any of a tablet, a smart phone, laptop computer, etc., and may include a display screen (e.g., a capacitive, inductive, resistive, or optical touchscreen), a chip-level or package-level integrated system 910, and a battery 915.

Whether disposed within the integrated system 910 illustrated in the expanded view 920, or as a stand-alone packaged chip within the server machine 906, packaged IC 950 may include a memory chip (e.g., RAM), or a processor chip (e.g., a microprocessor, a multi-core microprocessor, graphics processor, or the like) including at least one III-N power transistor having a laterally modulated polarization material thickness, for example as described elsewhere herein. The monolithic IC 950 may be further coupled to a board, a substrate, or an interposer 960 along with, one or more of a power management integrated circuit (PMIC) 930, RF (wireless) integrated circuit (RFIC) 925 including a wideband RF (wireless) transmitter and/or receiver (TX/RX) (e.g., including a digital baseband and an analog front end module further comprises a power amplifier on a transmit path and a low noise amplifier on a receive path), and a controller thereof 935. One or more of PMIC 930 and RFIC 925 may include at least one III-N power transistor having a laterally modulated polarization material thickness, for example as described elsewhere herein.

Functionally, PMIC 930 may perform battery power regulation, DC-to-DC conversion, etc., and so has an input coupled to battery 915 and with an output providing a current supply to other functional modules. As further illustrated, in the exemplary embodiment, RFIC 925 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. In alternative implementations, each of these board-level modules may be integrated onto separate ICs coupled to the package substrate of the monolithic IC 950 or within a single IC coupled to the package substrate of the monolithic IC 950.

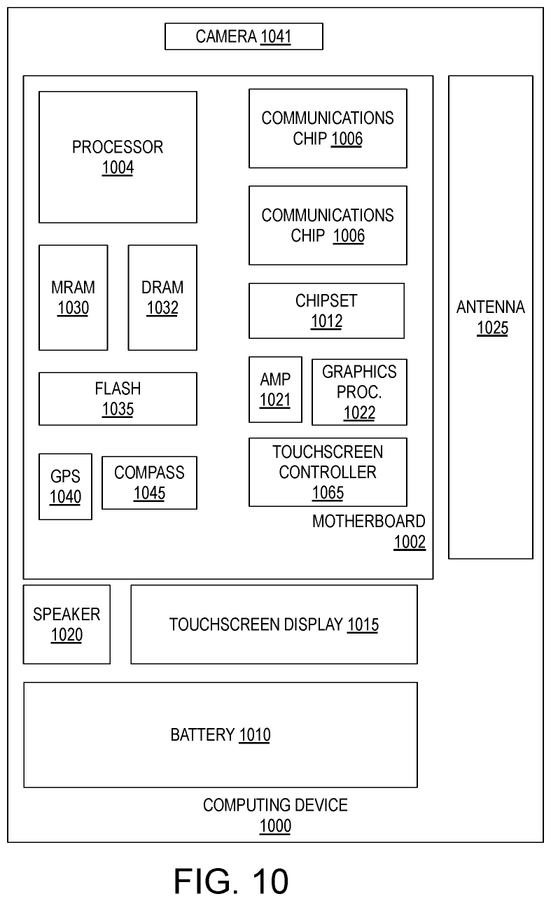

FIG. 10 is a functional block diagram of a computing device 1000, arranged in accordance with at least some implementations of the present disclosure. Computing device 1000 may be found inside platform 905 or server machine 906, for example. Device 1000 further includes a motherboard 1002 hosting a number of components, such as, but not limited to, a processor 1004 (e.g., an applications processor), which may further incorporate at least one III-N power transistor having a laterally modulated polarization material thickness, for example as described elsewhere herein, in accordance with some embodiments. Processor 1004 may be physically and/or electrically coupled to motherboard 1002. In some examples, processor 1004 includes an integrated circuit die packaged within the processor 1004. In general, the term “processor” or “microprocessor” may refer to any device or portion of a device that processes electronic data from registers and/or memory to transform that electronic data into other electronic data that may be further stored in registers and/or memory.

In various examples, one or more communication chips 1006 may also be physically and/or electrically coupled to the motherboard 1002. In further implementations, communication chips 1006 may be part of processor 1004. Depending on its applications, computing device 1000 may include other components that may or may not be physically and electrically coupled to motherboard 1002. These other components include, but are not limited to, volatile memory (e.g., DRAM 1032), non-volatile memory (e.g., MRAM 1030), flash memory 1035, a graphics processor 1022, a digital signal processor, a crypto processor, a chipset 1012, an antenna 1025, touchscreen display 1015, touchscreen controller 1065, battery 1010, audio codec, video codec, power amplifier 1021, global positioning system (GPS) device 1040, compass 1045, accelerometer, gyroscope, speaker 1020, camera 1041, and mass storage device (such as hard disk drive, solid-state drive (SSD), compact disk (CD), digital versatile disk (DVD), and so forth), or the like.

Communication chips 1006 may enable wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1006 may implement any of a number of wireless standards or protocols, including but not limited to those described elsewhere herein. As discussed, computing device 1000 may include a plurality of communication chips 1006. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others. One or more of communication chips 1006 may include at least one III-N power transistor having a laterally modulated polarization material thickness, for example as described elsewhere herein.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that embodiments other than those described in detail above may be practiced with modification and alteration without departing from the scope of the appended claims. For example the above embodiments may include specific combinations of features as further provided below:

In first examples, a transistor comprises a source coupled to a drain through a first group III-nitride (III-N) material, gate electrode between the source and drain, and a second III-N material over the first III-N material. A first portion of the second III-N material between the gate electrode and a first of the source and drain has a first thickness. A second portion of the second III-N material between the gate electrode and a second of the source and drain has a second thickness, less than the first thickness.

In second examples, for any of the first examples the first portion of the second III-N material is between the source and the gate electrode, and the second portion of the second III-N material is between the drain and the gate electrode.

In third examples, for any of the first or second examples the source or drain is laterally separated from an edge of the gate electrode by a first distance, and the second III-N material has the second thickness over the entire first distance.

In fourth examples, for any of the first through third examples the source or drain is laterally separated from an edge of the gate electrode by a first distance, and the second III-N material has the second thickness over less than the entire first distance.

In fifth examples, for any of the first through fourth examples the gate electrode has a gate width, and the second III-N material has the second thickness over the entire gate width.

In sixth examples, for any fifth examples, a third portion of the second III-N material between the gate electrode and the first III-N material has a third thickness that is less than the first thickness.

In seventh examples, for any of the sixth examples, the third thickness is more than the second thickness.

In eighth examples, for any of the sixth examples the third thickness is less than the second thickness.

In ninth examples, for any of the first through the eighth examples the first III-N material comprises Ga and N, and the second III-N material has a higher Al content than the first III-N material, the second thickness is no more than 80% of the first thickness.

In tenth examples, for any of the first through the ninth examples the second III-N material comprises AlₓGa₁₋ₓN, In_{y}Al_{1-y}N, or In_{y}Al_{1-y-z}Ga_{z}N; and x is between 0.25 and 0.4, y is less than 0.2, or z is less than 0.2.

In eleventh examples, for any of the first through the tenth examples the first III-N material comprises binary GaN, and a c-plane of the first and second III-N materials is no more than 10° from parallel to plane of an underlying substrate.

In twelfth examples, an integrated circuit (IC) comprises a first III-N transistor and a second III-N transistor. The first transistor further comprises a first source coupled to a first drain through a first body comprising a first group III-nitride (III-N) material, a first gate electrode between the first source and first drain, and a second III-N material over the first III-N material. A first portion of the second III-N material between the first gate electrode and a first of the source and drain has a first thickness, and a second portion of the second III-N material between first gate electrode and a second of the source and drain has a second thickness, less than the first thickness. The second transistor further comprises a second source coupled to a second drain through the a second body comprising the first group III-nitride (III-N) material. The second transistor further comprises a second gate electrode between the second source and second drain. The second III-N material is over the first III-N material, wherein the second III-N material between the second source and second drain, and beyond a sidewall of the second gate electrode, has a constant thickness substantially equal to the first thickness.

In thirteenth examples, for any of the twelfth examples the first drain is laterally spaced apart from the first gate electrode by a first distance. The second drain is laterally spaced apart from the second gate electrode by a second distance that no more than 10% longer than the first distance.

In fourteenth examples for any of the twelfth through thirteenth examples the first portion of the second III-N material is between the first source and the first gate electrode, and the second portion of the second III-N material is between the first drain and the first gate electrode.

In fifteenth examples, for any of the twelfth through the fourteen examples the second III-N material between the first gate electrode and the first III-N material has a thickness that is less than the first thickness.

In sixteenth examples, for any of the twelfth through fifteenth examples the first III-N material comprises Ga and N, and the second III-N material has a higher Al and In content than the first III-N material, and the second thickness is no more than 80% of the first thickness.

In seventeenth examples, a method of forming a transistor comprises receiving a workpiece comprising a first III-N material under a second III-N material, wherein the first III-N material has a first thickness. The method comprises forming a recess partially through the second III-N material, wherein within the recess the second III-N material has a second thickness, less than the first thickness. The method comprises forming a source and drain coupled to the first III-N material, the source and drain on opposite sides of the recess, and the method comprises forming a gate electrode between the recess and the source or between the recess and the drain.

In eighteenth examples, for any of the seventeenth examples forming the recess further comprises forming a mask with an opening over a portion of the second III-N material, and etching partially through the second III-N material.

In nineteenth examples, for any of the seventeenth through eighteenth examples etching partially through the second III-N material comprises etching through at least 20% of a thickness of the second III-N material.

In twentieth examples, for any of the seventeenth through nineteen examples the method further comprises depositing a passivation dielectric material over the second III-N material after forming the recess, the passivation dielectric occupying at least a portion of the recess.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A transistor, comprising:
a source coupled to a drain through a first group III-nitride (III-N) material;
a gate electrode between the source and drain; and
a second III-N material over the first III-N material, wherein a first portion of the second III-N material between the gate electrode and a first of the source and drain has a first thickness, and a second portion of the second III-N material between the gate electrode and a second of the source and drain has a second thickness, less than the first thickness.

2. The transistor of claim 1, wherein the first portion of the second III-N material is between the source and the gate electrode, and the second portion of the second III-N material is between the drain and the gate electrode.

3. The transistor of claim 1, wherein the source or drain is laterally separated from an edge of the gate electrode by a first distance, and the second III-N material has the second thickness over the entire first distance.

4. The transistor of claim 1, wherein the source or drain is laterally separated from an edge of the gate electrode by a first distance, and the second III-N material has the second thickness over less than the entire first distance.

5. The transistor of claim 1, wherein the gate electrode has a gate width, and the second III-N material has the second thickness over the entire gate width.

6. The transistor of claim 1, wherein a third portion of the second III-N material between the gate electrode and the first III-N material has a third thickness that is less than the first thickness.

7. The transistor of claim 6, wherein the third thickness is more than the second thickness.

8. The transistor of claim 6, wherein the third thickness is less than the second thickness.

9. The transistor of claim 1, wherein:
the first III-N material comprises Ga and N, and the second III-N material has a higher Al content than the first III-N material; and
the second thickness is no more than 80% of the first thickness.

10. The transistor of claim 9, wherein:
the second III-N material comprises AlₓGa₁₋ₓN, In_{y}Al_{1-y}N, or In_{y}Al_{1-y-z}Ga_{z}N; and
x is between 0.25 and 0.4, y is less than 0.2, or z is less than 0.2.

11. The transistor of claim 10, wherein:
the first III-N material comprises binary GaN;
a c-plane of the first and second III-N materials is no more than 10° from parallel to plane of an underlying substrate.

12. An integrated circuit (IC), comprising:
a first III-N transistor and a second III-N transistor, wherein:
the first transistor further comprises:
a first source coupled to a first drain through a first body comprising a first group III-nitride (III-N) material;
a first gate electrode between the first source and first drain; and
a second III-N material over the first III-N material, wherein a first portion of the second III-N material between the first gate electrode and a first of the source and drain has a first thickness, and a second portion of the second III-N material between first gate electrode and a second of the source and drain has a second thickness, less than the first thickness; and
the second transistor further comprises:
a second source coupled to a second drain through the a second body comprising the first group III-nitride (III-N) material;
a second gate electrode between the second source and second drain; and
the second III-N material over the first III-N material, wherein at least a portion of the second III-N material between the second source and second drain, and beyond a sidewall of the second gate electrode, has a constant thickness substantially equal to the first thickness.

13. The IC of claim 12, wherein:
the first drain is laterally spaced apart from the first gate electrode by a first distance; and
the second drain is laterally spaced apart from the second gate electrode by a second distance that no more than 10% longer than the first distance.

14. The IC of claim 13, wherein the first portion of the second III-N material is between the first source and the first gate electrode, and the second portion of the second III-N material is between the first drain and the first gate electrode.

15. The IC of claim 13, wherein the second III-N material between the first gate electrode and the first III-N material has a thickness that is less than the first thickness.

16. The IC of claim 15, wherein the first III-N material comprises Ga and N, and the second III-N material has a higher Al and In content than the first III-N material; and
the second thickness is no more than 80% of the first thickness.

17. A method of forming a transistor, the method comprising:
receiving a workpiece comprising a first III-N material under a second III-N material, wherein the first III-N material has a first thickness;
forming a recess partially through the second III-N material, wherein within the recess the second III-N material has a second thickness, less than the first thickness;
forming a source and drain coupled to the first III-N material, the source and drain on opposite sides of the recess; and
forming a gate electrode between the recess and the source or between the recess and the drain.

18. The method of claim 17, wherein forming the recess further comprises:
forming a mask with an opening over a portion of the second III-N material; and
etching partially through the second III-N material.

19. The method of claim 18, wherein etching partially through the second III-N material comprises etching through at least 20% of a thickness of the second III-N material.

20. The method of claim 17, further comprising depositing a passivation dielectric material over the second III-N material after forming the recess, the passivation dielectric occupying at least a portion of the recess.
